(19) United States
(12) Patent Application Publication
(10) Pub. No.: US 2019/0189359 A1
(43) Pub. Date: Jun. 20, 2019

(54) PRINTABLE CONDUCTIVE COMPOSITE SLURRY, CAPACITOR AND METHOD FOR MANUFACTURING CAPACITOR

(71) Applicant: APAQ TECHNOLOGY CO., LTD., Miaoli County (TW)

(72) Inventors: CHIEH LIN, HSINCHU COUNTY (TW); SHANG-CHE LAN, KAOHSIUNG CITY (TW); MING-TSUNG CHEN, CHANGHUA COUNTY (TW)

(21) Appl. No.: 16/218,753

(22) Filed: Dec. 13, 2018

(30) Foreign Application Priority Data
Dec. 15, 2017 (TW) 106144195

(51) Int. Cl. H01G 9/028; H01G 9/15; H01B 1/22; H01B 1/12; H01G 11/48; H01B 5/14; H05K 1/09; H01G 9/012; H01G 11/60

(52) U.S. Cl. CPC H01G 9/028; H01G 9/15; H01B 1/22; H01B 1/127; H01G 11/60; H01B 5/14; H05K 1/092; H01G 9/012; H01G 11/48

(57) ABSTRACT

A printable conductive composite slurry, a capacitor using the same and a method for manufacturing the capacitor are provided. The method includes forming a conductive polymer layer on a cathode portion of a capacitor element and printing a conductive composite slurry onto the conductive polymer layer to at least cover a portion of the conductive polymer layer that is disposed on an outer edge of the cathode portion. The printable conductive composite slurry includes a conductive material and a solvent, and has a solid content of at least 4%, a pH value ranging from 2 to 8 and a viscosity higher than 500 poise.

### CROSS-REFERENCE TO RELATED PATENT APPLICATION

This application claims the benefit of priority to Taiwan Patent Application No. 106144195, filed on Dec. 15, 2017. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a conductive composite slurry, a capacitor and a method for manufacturing the capacitor, and more particularly to a printable conductive composite slurry, a capacitor using the same and a method for manufacturing the capacitor.

### BACKGROUND OF THE DISCLOSURE

Capacitors are necessary components of home appliances, computer motherboards and peripherals, power supplies, communication products and automobiles, and are mainly used to provide bypassing, coupling, filtering, oscillation, or transforming functions. Capacitors can be categorized into aluminum electrolytic capacitors, tantalum electrolytic capacitors, multilayer ceramic capacitors, and thin-film capacitors according to their materials and use. Solid electrolytic capacitor known in the related art have advantages of small size, large capacitance and good frequency properties, and can be used for decoupling a power circuit of a central processing unit. In the solid electrolytic capacitor, a solid electrolyte is used to replace the liquid electrolyte to serve as a cathode. Conductive polymers have advantages of high electrical conductivity and easy processing, and have been widely applied to cathode materials of the solid electrolytic capacitors.

However, the conventional method for manufacturing the solid electrolytic capacitor still has certain issues that need to be improved.

### SUMMARY OF THE DISCLOSURE

In response to the above-referenced technical inadequacies, the present disclosure provides a printable conductive composite slurry, a capacitor and a method for manufacturing the capacitor for improving electrical properties and a manufacturing process of the capacitor.

In one aspect, the present disclosure provides a printable conductive composite slurry which includes a conductive material and a solvent. The printable conductive composite slurry has a solid content of at least 4%, a pH value between 2 and 8 and a viscosity higher than 500 poise.

In one aspect, the present disclosure provides a capacitor having a protective layer, which includes at least one capacitor element. A cathode portion of the at least one capacitor element is covered by a conductive polymer layer and the conductive polymer layer is covered by the protective layer, such that the conductive polymer layer is disposed between the cathode portion and the protective layer. The conductive polymer layer is formed from a printable conductive composite slurry. The printable conductive composite slurry includes a conductive material and a solvent, and has a solid content of at least 4%, a pH value between 2 and 8 and a viscosity higher than 500 poise.

In one aspect, the present disclosure provides a method for manufacturing a capacitor which includes forming a conductive polymer layer on a cathode portion of a capacitor element and printing a conductive composite slurry onto the conductive polymer layer to at least cover a portion of the conductive polymer layer that is disposed on an outer edge of the cathode portion. The printable conductive composite slurry includes a conductive material and a solvent, and has a solid content of at least 4%, a pH value between 2 and 8 and a viscosity higher than 500 poise.

One of the advantages of the present disclosure is that the capacitor using a printable conductive composite slurry having a solid content of at least 4%, a pH value between 2 and 8 and a viscosity higher than 500 poise, so that the coverage and planarity of a conductive polymer material based layer can be increased. Furthermore, the method for manufacturing the capacitor includes a step of printing the printable conductive composite slurry onto the conductive polymer layer to at least cover a portion of the conductive polymer layer that is disposed on an outer edge of the cathode portion. Therefore, the manufacturing efficiency can be increased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a cross sectional view of a capacitor applying a printable conductive composite slurry according to embodiments of the present disclosure.

FIG. 2 is a side schematic view of a capacitor package structure including a plurality of capacitors each of which is shown in FIG. 1.

FIG. 3 is a flowchart of a method for manufacturing the capacitor according to the embodiments of the present disclosure.

FIG. 4 is a side view illustrating a step of the method for manufacturing the capacitor according to the embodiments of the present disclosure.

FIG. 5 is a top view illustrating the step in FIG. 4.

FIG. 6 is another top view illustrating the step in FIG. 4.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

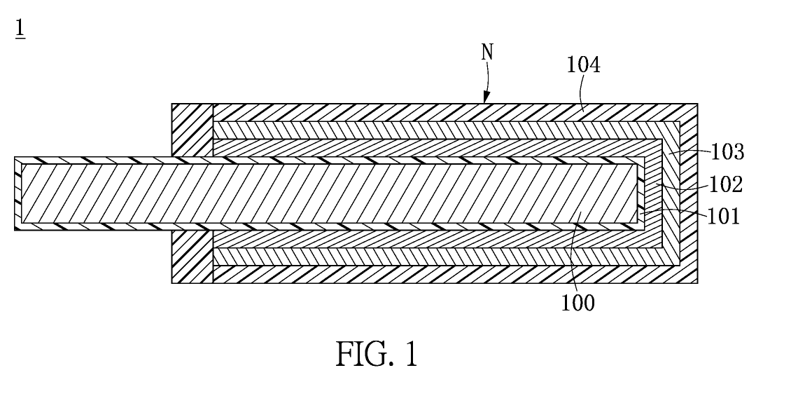

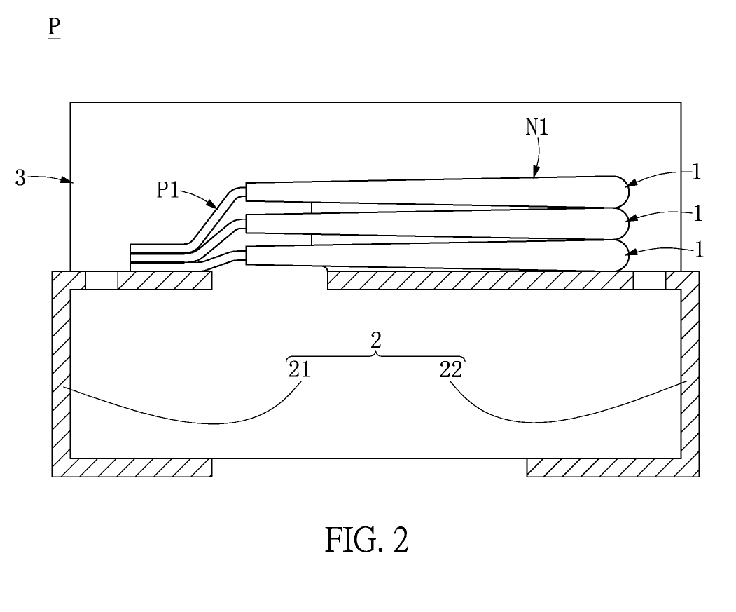

Referring to FIGS. 1 and 2, FIG. 1 is a cross sectional view of a capacitor applying a printable conductive composite slurry according to embodiments of the present disclosure, and FIG. 2 is a side schematic view of a capacitor package structure including a plurality of capacitors each of which is shown in FIG. 1.

Specifically speaking, as shown in FIG. 1, the printable conductive composite slurry of the present disclosure can be applied to a conductive layer 102 that is formed on a cathode portion N of a capacitor 1. As shown in FIG. 2, a plurality of capacitors 1, in which the cathode portions N are stacked on top of one another, are disposed to form a stacked-type solid electrolytic capacitor package structure P together with a lead frame 2 and a package body 3.

In the present embodiment, the capacitor 1 as shown in FIG. 1 includes a metal foil 100, an oxide layer 101 covering the metal foil 100, a conductive layer 102 covering a portion of the oxide layer 101, and a carbon paste layer 103 covering the conductive layer 102, and a silver paste layer 104 covering the carbon paste layer 103. The structure of the capacitor 1 can be changed according to particular requirements. The conductive layer 102 mainly serves as a solid electrolyte of the capacitor 1.

The stacked-type solid electrolytic capacitor package structure P as shown in FIG. 2 includes a plurality of the capacitors 1 stacked on top of one another in sequence. The stacked-type solid electrolytic capacitor package structure P further includes a lead frame 2. The lead frame 2 includes a first conductive terminal 21 and a second conductive terminal 22 spaced apart from the first conductive terminal 21 at a predetermined distance. The capacitors 1 stacked together co-define a first positive electrode portion P1 electrically connected to the first conductive terminal 21 and a first negative electrode portion N1 electrically connected to the second conductive terminal 22. The capacitors 1, which are stacked together and electrically connected to each other, can be encapsulated in a package body 3 to form the stacked-type solid electrolytic capacitor package structure P.

The term “capacitor element” used herein refers to the metal foil 100 of the capacitor 1 or the metal foil 100 provided with at least one functional layer. The printable conductive composite slurry, the capacitor using the same and the method for manufacturing the capacitor of the present disclosure are used to modify the material, structure and formation process of the conductive layer 102 that is formed on the metal foil 100.

The printable conductive composite slurry includes a conductive material and a solvent. The conductive material can be any material utilized for the solid electrolyte of the capacitor. In the present disclosure, the conductive material can include a conductive polymer such as polyaniline (PAni), polypyrrole (PPy), polythiophene (PTh) or poly(3,4-ethylenedioxythiophene)/polystyrene sulfonate (PEDOT:PSS). The solvent can be water or an organic solvent such as ethanol. Preferably, the conductive material is an emulsifier-modified PEDOT:PSS for increasing the dispersibility and electrical properties.

In the present disclosure, the emulsifier can be selected from the group consisting of polyols, cetyl trimethyl ammonium bromide (CTAB), dodecyl trimethyl ammonium bromide (DTAB), polyethylene glycol monostearate, sodium dodecyl sulfate (SDS), sodium dodecyl benzene sulfonate (SDBS), oleic acid and its derivatives, glycerol monostearate, polyoxyethylene monooleate, P.O.E.(10)oleyl alcohol, sorbitan monolaurate, sorbitan monopalmitate, sorbitan monostearate, sorbitan tristearate, sorbiatan monooleate, sorbitan sesquiolate, sorbitan tribleate, polyoxyethylene oxypropylene oleate, polyoxyethylene sorbitol hexastearate, polyoxyethylene esters of mixed fatty and resin acids, D-sorbital, polyoxyethylene sorbitol lanolin derivative, polyoxyethylene alkyl aryl ether, polyoxyethylene sorbitol beeswax derivative, polyoxyethylene monopalmitate, polyoxyethylene glycol monopalmitate, polyoxyethylene oxypropylene oleate, tetraethylene glycol monolaurate, polyoxyethylene monolaurate, polyoxyethylene lauryl ether, polyoxyethylene enemonooleate, polyoxyethylene monooleate, hoxaethylene glycol monostearate, propylene glycol fatty acid ester, polyoxyethylene oxypropylene stearate, N-cetyl N-ethyl morpholinium ethosulfate, alkyl aryl sulfonate, polyoxypropylene stearate, polyoxyethylene laurylether, polyoxyethylene stearyl alcohol, diethylene glycol monolaurate, sorbitan monolaurate, ethylene glycol diglycidyl ether, polyethylene glycol diglycidyl ether, propanediol diglycidyl ether, polypropanediol diglycidyl ether, 1,2,3-propanetriol glycidyl ethers, and butanediol diglycidyl ether. Preferably, the emulsifier is a polyol. More preferably, the emulsifier is polyethylene glycol or polypropylene glycol. It should be noted that the emulsifier can be a substance with the function of surfactant, but is not limited thereto. In addition, one or more emulsifiers can be used to modify PEDOT:PSS.

The printable conductive composite slurry can further include one or more additives selected from a conductive auxiliary agent, a pH adjusting agent, an agglutinating agent, a thickening agent, an adhesive, and a cross-licking agent. For example, the conductive auxiliary agent can be a high melting-point solvent that is ethylene glycol, glycerol, dimethyl hydrazine (DMSO), sorbitol, or N-methylpyrrolidone (NMP). The pH adjusting agent can be ethanolamine, diethanolamine, triethanolamine, dimethylethanolamine, diamines (e.g., ethylenediamine and propylenediamine), or triamines. The pH adjusting agent can also be sulfuric acid, nitric acid, acetic acid or p-toluenesulfonic acid. The agglutinating agent can be various carboxylic acids or carboxylic acid polymers or polyacrylic acid. The thickening agent can be polyethylene glycol or alkyl cellulose having a molecular weight between 1000 and 40000. The adhesive can be a polyurethane, polyester, polyacrylate or polyvinyl alcohol based adhesive. The cross-licking agent can be a silane coupling agent.

The printable conductive composite slurry has a solid content of at least 4%, a pH value between 2 and 8 and a viscosity higher than 500 poise. That is to say, the content of the ingredients of the printable conductive composite slurry each has been adjusted, so that the printable conductive composite slurry has specific physical properties. Accordingly, the electrical properties of the printable conductive composite slurry can be increased, and the printable conductive composite slurry can be printed on the capacitor element to form a protective layer 5.

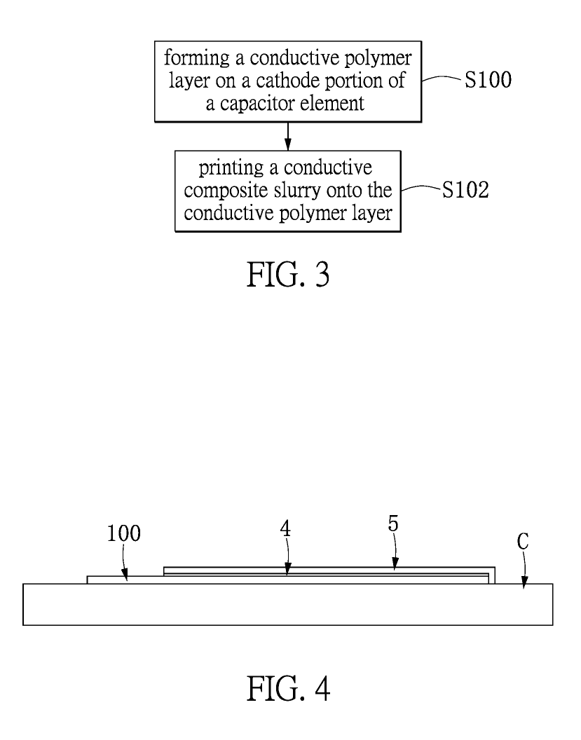

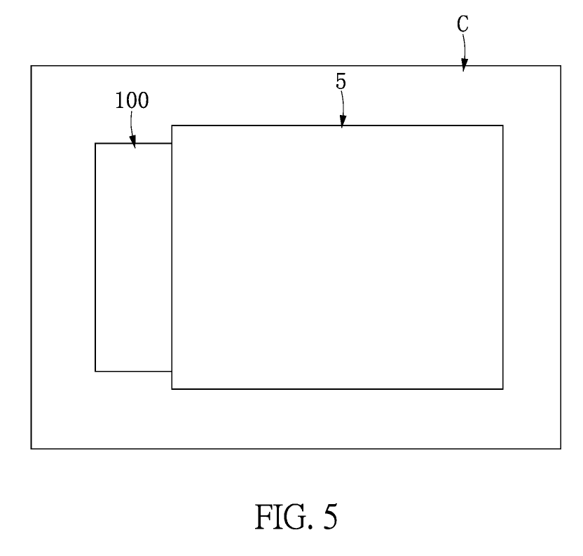

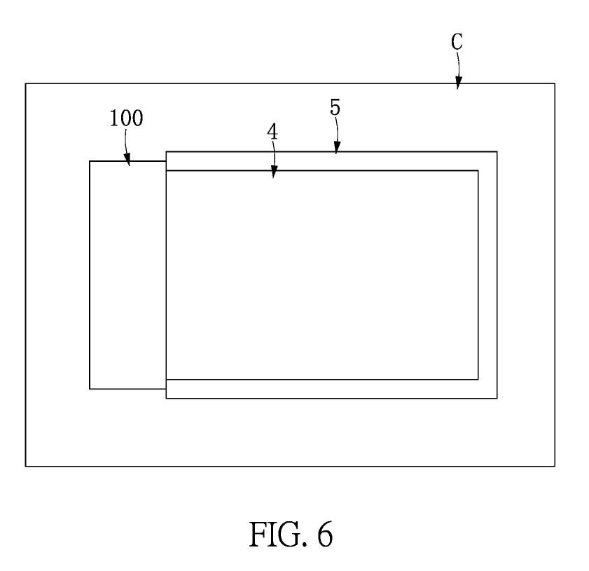

Referring to FIGS. 3 to 6, FIG. 3 is a flowchart of a method for manufacturing the capacitor according to the embodiments of the present disclosure, FIG. 4 is a side view illustrating a step of the method for manufacturing the capacitor, and FIGS. 5 and 6 are top views illustrating the step.

Reference is first made to FIG. 3. The method for manufacturing the capacitor includes the following steps. Step S100 is forming a conductive polymer layer on a cathode portion of a capacitor element. Step S102 is printing a printable conductive composite slurry onto the conductive polymer layer to at least cover a portion of the conductive polymer layer that is disposed on an outer edge of the cathode portion. It should be noted that, the printable conductive composite slurry used in the step S102 has a solid content of at least 4%, a pH value between 2 and 8 and a viscosity higher than 500 poise. Furthermore, the printable conductive composite slurry can have a solid content of less than 25%.

Specifically speaking, in step S100, the conductive polymer layer 4 can be formed by dipping the capacitor element in a conductive dispersion liquid. The conductive dispersion liquid can include a conductive polymer material, a dispersing agent, and other functional additives. The conductive polymer material can be the same as or different from the aforesaid conductive material of the printable conductive composite slurry. The dispersing agent liquid can be water. The types of other functional additives are not limited in the present invention.

In the present embodiment, the step of forming the conductive polymer layer 4 further includes disposing the conductive dispersion liquid on the capacitor element such that a portion of the conductive dispersion liquid fills into pores of the cathode portion N and drying the conductive dispersion liquid to form the conductive polymer layer 4. That is to say, a portion of the conductive dispersion liquid can be filled into the pores of the cathode portion N formed in the manufacturing process by dipping, so that the impregnation rate of the capacitor element can be increased.

It should be noted that, the method for forming the conductive polymer layer 4 is not limited to dipping. For example, aside from directly applying the conductive polymer material onto the cathode portion N, the conductive polymer layer 4 can be formed by performing an in-situ chemical polymerization method on the cathode portion N. The conductive polymer layer 4 can also be formed by performing a chemical polymerization method on the cathode portion N and then dipping the cathode portion N in the conductive polymer material.

Reference is next made to FIG. 4. FIG. 4 is a side view showing the step of printing the printable conductive composite slurry onto the conductive polymer layer 4. In step S102, the printable conductive composite slurry having a high viscosity is printed on the conductive polymer layer 4.

As shown in FIG. 4, the capacitor element is disposed on a surface of a supporting board C. The capacitor element has a metal foil 100 and an oxide layer 101 formed on the metal foil 100. The supporting board C can be made of polytetrafluoroethylene (PTFE or Teflon®).

In a certain example, the capacitor element (i.e., the metal foil 100) disposed on the supporting board C is provided with the conductive polymer layer 4. The printable conductive composite slurry is disposed on the conductive polymer layer 4 to form the protective layer 5. In the present disclosure, the printable conductive composite slurry is dried to form the protective layer 5 after being printed on the conductive polymer layer 4 to form the protective layer 5.

It should be noted that although the protective layer 5 as shown in FIG. 4 is printed on a surface of the capacitor element (i.e., the metal foil 100), in practice, another protective layer 5 can be formed on another surface of the capacitor element by the same means.

Furthermore, as described in the present disclosure, the protective layer 5 is formed by printing so that the shape and coverage area can be adjusted by using a mold with a desired shape or profile. Referring to FIGS. 5 and 6, FIGS. 5 and 6 are different top views showing the same step in FIG. 4.

Specifically speaking, in one embodiment of the present disclosure as shown in FIG. 5, the protective layer 5 formed by printing can completely cover the conductive polymer layer 4 disposed on the cathode portion N of the capacitor element. The protective layer 5 also completely covers the peripheral edge of the capacitor element.

In another embodiment of the present disclosure as shown in FIG. 6, the protective layer 5 formed by printing only covers the peripheral edge of the capacitor element. That is to say, a portion of the conductive polymer layer 4 disposed on the cathode portion N of the capacitor element exposes from the protective layer 5. It should be noted that, the protective layer 5 still completely covers the peripheral edge of the capacitor element. Specifically speaking, the protective layer 5 at least covers three peripheral edge sections of the cathode portion N of the capacitor element.

Specifically speaking, the difference between FIGS. 5 and 6 is the position of the protective layer 5 with respect to the cathode portion N of the capacitor element. In practice, this position parameter can be determined according to the formation steps of the conductive polymer layer 4. For example, if the conductive polymer layer 4 formed on the cathode portion N of the capacitor element reaches a predetermined thickness, the protective layer 5 formed subsequently can only cover the peripheral edge of the capacitor element. Therefore, the manufacturing costs can be saved.

By the aforesaid structural design, a laminate structure having the protective layer 5, which is disposed on the cathode portion N of the capacitor element, can reach a sufficient thickness, wherein a portion of the conductive polymer material of the conductive polymer layer 4 and the protective layer 5 fills into the pores of the cathode portion N of the capacitor element. Therefore, the electrical properties of the capacitor package structure P including the capacitor elements can be ensured. Specifically speaking, the capacitor of the present disclosure, compared to the conventional capacitor without the protective layer 5, has a relatively low leakage current (LC).

It should be noted that, the conventional method provides the plurality of conductive polymer layers on the cathode portion N by repeatedly executing a coating step. The present method uses the printable conductive composite slurry having specific physical properties to form the protective layer 5 having a predetermined thickness at a time, thereby saving the manufacturing costs and increasing the manufacturing efficiency.

By the aforesaid method, the present disclosure further provides a capacitor having the protective layer 5. The capacitor includes at least one capacitor element. The cathode portion N of the at least one capacitor element is covered by the conductive polymer layer 4 and the conductive polymer layer 4 is covered by the protective layer 5, such that the conductive polymer layer 4 is disposed between the cathode portion N and the protective layer 5. The protective layer 5 is formed from the aforesaid printable conductive composite slurry, wherein the printable conductive composite slurry includes a conductive material and a solvent, and has a solid content of at least 4%, a pH value between 2 and 8 and a viscosity higher than 500 poise.

The details of the ingredients of the printable conductive composite slurry and the steps of the method for manufacturing the capacitor by using the printable conductive composite slurry are described above and will not be reiterated herein.

One of the advantages of the present disclosure is that the capacitor using the printable conductive composite slurry having a solid content of at least 4%, a pH value between 2 and 8 and a viscosity higher than 500 poise, so that the coverage and planarity of the conductive polymer material based layer can be increased. Furthermore, the method for manufacturing the capacitor includes the step of printing the printable conductive composite slurry onto the conductive polymer layer to at least cover a portion of the conductive polymer layer that is disposed on an outer edge of the cathode portion. Therefore, the manufacturing efficiency can be increased.

Specifically speaking, the present invention uses the printable conductive composite slurry having specific physical properties such as a solid content, a pH value and a viscosity to improve the electrical performance of the capacitor and to simplify the manufacturing process. Furthermore, the printable conductive composite slurry is disposed on the cathode portion N of the capacitor element by printing. Therefore, the shape and coverage area of the protective layer 5 can be adjusted by using a mold with a desired shape or profile, thereby increasing the flexibility of the manufacturing process.

In addition, the printable conductive composite slurry formed by printing and having specific physical properties can ensure the planarity of the top surface of the protective layer 5. Therefore, the protective layer 5 can cover the conductive polymer layer 4 and the peripheral edge of the capacitor element.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A printable conductive composite slurry comprising a conductive material and a solvent, wherein the printable conductive composite slurry has a solid content of at least 4%, a pH value between 2 and 8 and a viscosity higher than 500 poise.

2. The printable conductive composite slurry according to claim 1, further comprising one or more additives selected from a conductive auxiliary agent, a pH adjusting agent, an agglutinating agent, a thickening agent, an adhesive, and a cross-licking agent.

3. The printable conductive composite slurry according to claim 1, wherein the conductive material is poly(3,4-ethylenedioxythiophene)/polystyrene sulfonate (PEDOT:PSS) modified by an emulsifier.

4. The printable conductive composite slurry according to claim 2, wherein the thickening agent is polyethylene glycol or alkyl cellulose having a molecular weight between 1000 and 40000.

5. A capacitor comprising at least one capacitor element, wherein a cathode portion of the at least one capacitor element is covered by a conductive polymer layer and the conductive polymer layer is covered by a protective layer such that the conductive polymer layer is disposed between the cathode portion and the protective layer, wherein the conductive polymer layer is formed from a printable conductive composite slurry including a conductive material and a solvent, and wherein the printable conductive composite slurry has a solid content of at least 4%, a pH value between 2 and 8 and a viscosity higher than 500 poise.

6. The capacitor according to claim 5, wherein the conductive polymer layer is completely covered by the protective layer.

7. A method for manufacturing a capacitor, comprising:
forming a conductive polymer layer on a cathode portion of a capacitor element; and
printing a conductive composite slurry onto the conductive polymer layer to at least cover a portion of the conductive polymer layer that is disposed on an outer edge of the cathode portion;
wherein the printable conductive composite slurry includes a conductive material and a solvent, and has a solid content of at least 4%, a pH value between 2 and 8 and a viscosity higher than 500 poise.

8. The method according to claim 7, wherein the step of forming the conductive polymer layer further includes
disposing a conductive dispersion liquid on the capacitor element such that a portion of the conductive dispersion liquid fills into pores of the cathode portion; and
drying the conductive dispersion liquid that is disposed on the capacitor element to form the conductive polymer layer.

9. The method according to claim 7, further comprising: drying the conductive composite slurry printed on the conductive polymer layer to form a protective layer.

10. The method according to claim 8, wherein the conductive dispersion liquid is disposed on the capacitor element by dipping.
